(19) United States
(12) Patent Application Publication
(10) Pub. No.: US 2009/0203198 A1
(43) Pub. Date: Aug. 13, 2009

(54) SEMICONDUCTOR MANUFACTURING APPARATUS AND SEMICONDUCTOR MANUFACTURING METHOD USING THE SAME

(75) Inventor: Moon-Min SEO, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/362,251

(22) Filed: Jan. 29, 2009

(30) Foreign Application Priority Data
Feb. 12, 2008 (KR) 2008-0012485

(51) Int. Cl. H01L 21/223; C23C 16/54; H01L 21/30

(52) U.S. Cl. 438/513; 118/723 E; 438/778; 257/E21.143; 257/E21.211

(57) ABSTRACT

A semiconductor manufacturing apparatus and method are disclosed in which the apparatus comprises a reaction tube configured to hold one or more wafers, a spray pipe coupled to the reaction tube for spraying reaction gas into the reaction tube, and a plurality of electrodes used to convert the reaction gas to a plasma state. The electrodes include a cathode and an anode plasma electrode arranged for exciting reaction gas exiting the spray pipe to a plasma state prior to entry into the reaction tube. A switching device is coupled to both the cathode and anode plasma electrode and configured to switch a polarity of a high voltage applied to each of the cathode and anode to prevent a build-up of positive plasma reaction gas ions on the cathode during repeated processing steps.

### CROSS-REFERENCE TO RELATED APPLICATIONS

This application claims priority under 35 U.S.C. §119 from Korean Patent Application 10-2008-0012485, filed on Feb. 12, 2008, the contents of which are hereby incorporated by reference in their entirety for all purposes as if fully set forth herein.

### BACKGROUND

1. Field of the Invention

The present invention relates to semiconductor manufacturing apparatuses, and more particularly, to a semiconductor manufacturing apparatus performing a deposition or diffusion process, and a semiconductor manufacturing method using the same.

2. Description of the Related Art

In general, semiconductor devices are manufactured through selective and repeated execution on a wafer of photo processes, etching processes, diffusion processes, ion implantation processes, etc. The purpose of the deposition and diffusion processes are to form a thin film of given thickness on the wafer in a low or high temperature atmosphere or to diffuse a conductive impurity on the thin film.

Deposition processes for forming thin films can be characterized as using either a physical vapor deposition technique or a chemical vapor deposition technique. In an actual semiconductor manufacturing process, most thin films except a metal thin film are formed through the chemical vapor deposition technique. Further the diffusion process is used to thermally diffuse conductive impurities such as phosphorus in a single crystal silicon or polysilicon at about 700° C. or more, or obtain a thermal oxide by heating the wafer in an oxygen atmosphere, to perform annealing, baking, etc.

Most semiconductor manufacturing apparatuses conducting a diffusion process and/or a deposition process are a batch type, increasing productivity by processing a number of wafers at a time. Batch type semiconductor manufacturing apparatuses are therefore important factors in cutting production unit costs since a greater number of wafers can be processed within a reaction tube at the same time. In a typical example, the reaction tube may be adapted to load about 70 sheets to about 150 sheets of wafers therein and perform diffusion and deposition processes therefor.

The plurality of wafers may be multistaged within a boat and placed into the reaction tube. Thus the reaction tube is formed in a bell shape to store the plurality of wafers when stacked in a multistage.

Such batch type semiconductor manufacturing apparatuses are used to form various kinds of interlayer insulation layers such as SiO₂, PSG(Phosphor Silicate Glass), P(Plasma)-SiO, P(Plasma)-SiN, SOG(Spin On Glass), Si₃N₄ etc. Here the Si₃N₄ layer has a high dielectric permittivity and density as compared with the SiO₂ layer and thus has a dominant insulation characteristic and resistance to an etch. Thus, the Si₃N₄ layer provides a stack structure of “ONO structure” together with a silicon oxide layer having dominant interfacial properties, or may be used as an etch stopper layer in an etching process of etching a silicon oxide layer.

A source gas supplied into the reaction tube to form the Si₃N₄ layer is gas from a silane-group such as SiH₄, SiH₂Cl₂, Si₂Cl₆, 3-BIS BTBAS etc. The silane-group gas is known to react as a reaction gas through heat CVD (Chemical Vapor Deposition) with heat treatment of 500° C. or more and thus deposit a thin film. For example, SiH₂Cl₂ and NH₃ or Si₂Cl₆ and NH3 may form a silicon nitride layer, reacting to the high-temperature heat treatment.

However the high-temperature heat treatment process impacts the heat budget of the process, thereby decreasing an electrical characteristic of the thin film formed on a wafer in the semiconductor manufacturing process. Thus, it is desired during a deposition process when forming a silicon nitride layer to substantially reduce the heat treatment.

The research and development of an atomic layer deposition (ALD) method as a deposition process technology to satisfy such a requirement is becoming more important. In the atomic layer deposition method, source gas and reaction gas are alternately supplied into the reaction tube to sequentially form thin films one layer by one layer on a plurality of wafers. The reaction of the source gas and reaction gas is limited to the surface of wafer, instead of on the entire reaction tube, in forming a silicon nitride layer. At this time, to increase reaction efficiency and properties, the reaction gas is excited to a plasma state and then flowed onto the plurality of wafers.

A semiconductor manufacturing apparatus according to a conventional art performing a deposition process by exciting a reaction gas to a plasma state is disclosed in U.S. Patent Application No. 2006-0090851. In the conventional semiconductor manufacturing apparatus, pluralities of electrodes carrying high voltage are adapted to excite reaction gas such as ammonia sprayed from a spray pipe. The pluralities of electrodes are divided into an anode electrode and a cathode electrode, and a high voltage positive pole and negative electrode is each fixedly applied thereto. Further the anode electrode and the cathode electrode are covered with quartz for protection. Moreover, when the reaction tube is formed of quartz, the anode electrode and cathode electrode are adapted to oppose each other outside the reaction tube. A radio frequency (RF) voltage is applied to excite reaction gas to a plasma state, the reaction gas being sprayed from the reaction tube onto a plurality of wafers.

However, in the semiconductor manufacturing apparatus according to a conventional art, reaction gas ions charged into a plasma state of positive pole are concentrated on the quartz adjacent the cathode electrode; thus the quartz may be easily damaged, causing particles and decreasing a production yield.

### SUMMARY

Accordingly, some embodiments of the invention provide a semiconductor manufacturing apparatus and a semiconductor manufacturing method using the same, which is capable of preventing quartz from being damaged by reaction gas ions concentrated to only any one of a plurality of electrodes, and preventing an occurrence of particles, thereby increasing a production yield.

A semiconductor manufacturing apparatus and method are disclosed in which the apparatus comprises a reaction tube configured to hold one or more wafers, a spray pipe coupled to the reaction tube for spraying reaction gas into the reaction tube, and a plurality of electrodes used to convert the reaction gas to a plasma state. The electrodes include a cathode and an anode plasma electrode arranged for exciting reaction gas exiting the spray pipe to a plasma state prior to entry into the reaction tube. A switching device is coupled to both the cathode and anode plasma electrode and configured to switch a polarity of a high voltage applied to each of the cathode and anode to prevent a build-up of positive plasma reaction gas ions on the cathode during repeated processing steps.

According to another aspect of the invention, a semiconductor manufacturing apparatus comprises a boat for storing a plurality of wafers; at least one reaction tube adapted to surround a periphery of the boat; a spray pipe connected along an inner wall of the reaction tube for spraying reaction gas onto the plurality of wafers loaded into the boat; and a plurality of plasma electrodes adapted in parallel with the spray pipe and along both sides of outer wall of the reaction tube centering on the spray pipe, and adapted so that high voltage polarities of DC (Direct Current) component to excite the reaction gas sprayed from the spray pipe to a plasma state are mutually inverted and applied thereto.

The semiconductor manufacturing apparatus may comprise a high voltage generator for generating the high voltage by using power source supplied from the outside, a switching device for switching a polarity of the high voltage generated in the high voltage generator, and applying the voltage to the plurality of plasma electrodes, and a controller for outputting a control signal to switch the polarity of the high voltage. The switching device may switch a polarity of the high voltage applied to the plurality of plasma electrodes in a unit of deposition or diffusion process performed in the reaction tube. The switching device may comprise a plurality of power terminals coupled to the high voltage generator, a plurality of electrode terminals coupled with the plurality of plasma electrodes, and a plurality of switching bars bridging and switched between the plurality of electrode terminals and the plurality of power terminals.

According to another embodiment of the invention, a semiconductor manufacturing method comprises entering a plurality of first wafers loaded in a boat into a reaction tube; applying a high voltage of DC component to a plurality of plasma electrodes during a supply of reaction gas into the reaction tube, and thus exciting the reaction gas to a plasma state, and performing a deposition process or diffusion process forming a thin film of a given thickness on the plurality of first wafers by supplying source gas into the reaction tube; discharging the plurality of first wafers from the reaction tube, and entering a plurality of second wafers into the reaction tube; and applying a DC high voltage having a polarity opposite to a polarity in the plurality of first wafers to the plurality of plasma electrodes while reaction gas is supplied into the reaction tube, and thus exciting the reaction gas to a plasma state, and then performing a deposition or diffusion process to form a thin film on the plurality of second wafers by supplying source gas into the reaction tube.

As described above, according to some embodiments of the invention, a damage of a reaction tube causable by reaction gas ions of a plasma state concentrated on a cathode electrode can be prevented by using a switching device converting a polarity of high voltage applied to a plurality of plasma electrodes, and a pollution of particles generated by a damage of the reaction tube can be prevented, thereby increasing a production yield.

### BRIEF DESCRIPTION

The above and other features of some embodiments of the invention will become readily apparent from the description that follows, with reference to the attached drawings in which:

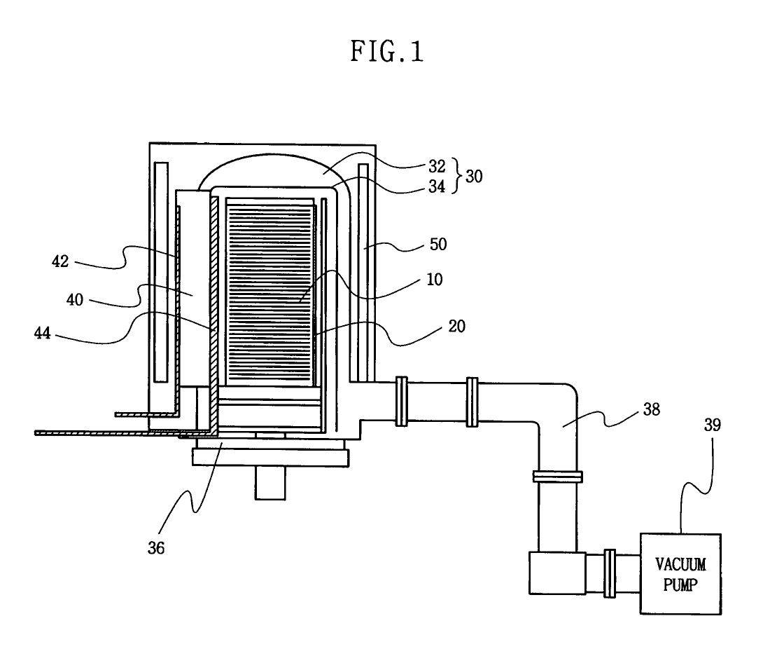

FIG. 1 is a sectional view schematically illustrating a semiconductor manufacturing apparatus according to an embodiment of the invention;

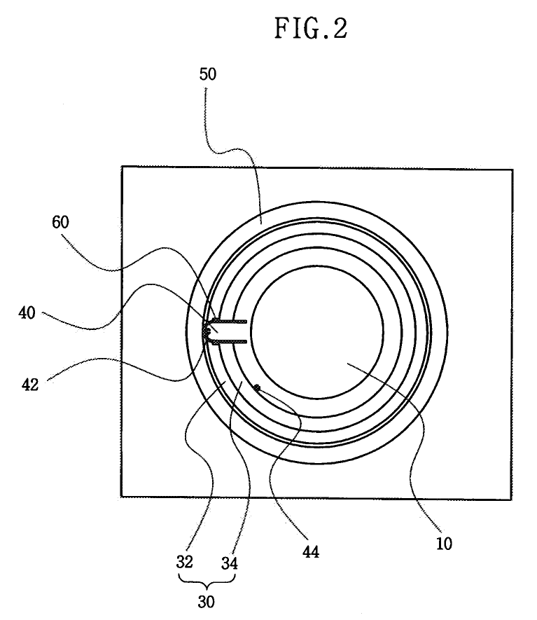

FIG. 2 is a plan view of FIG. 1;

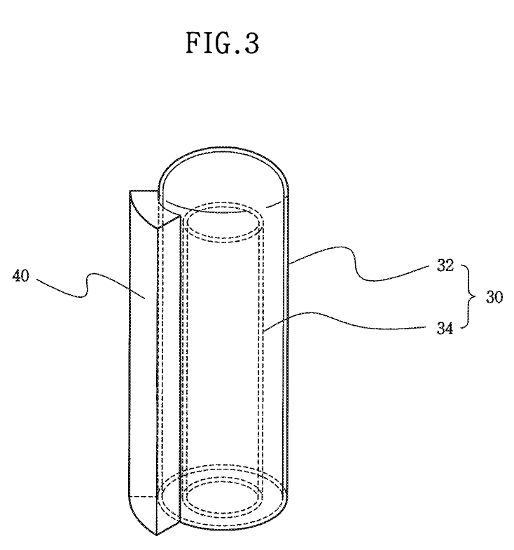

FIG. 3 is a perspective view illustrating a reaction tube of FIGS. 1 and 2;

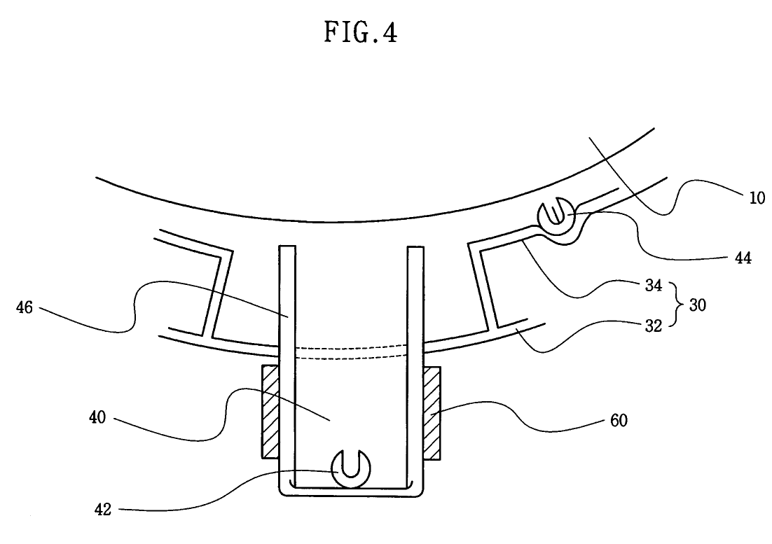

FIG. 4 is a plan view illustrating plasma electrodes surrounding a plasma box of FIGS. 1 and 2;

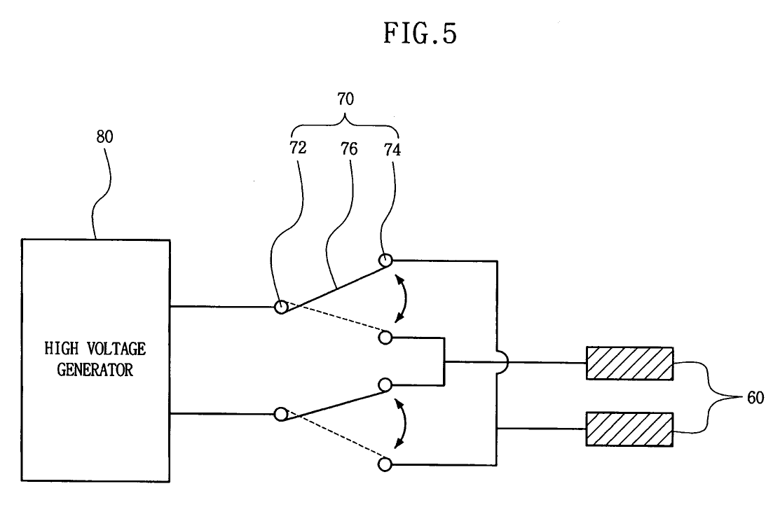

FIG. 5 is a circuit diagram schematically illustrating a switching device configured according to an embodiment of the invention; and

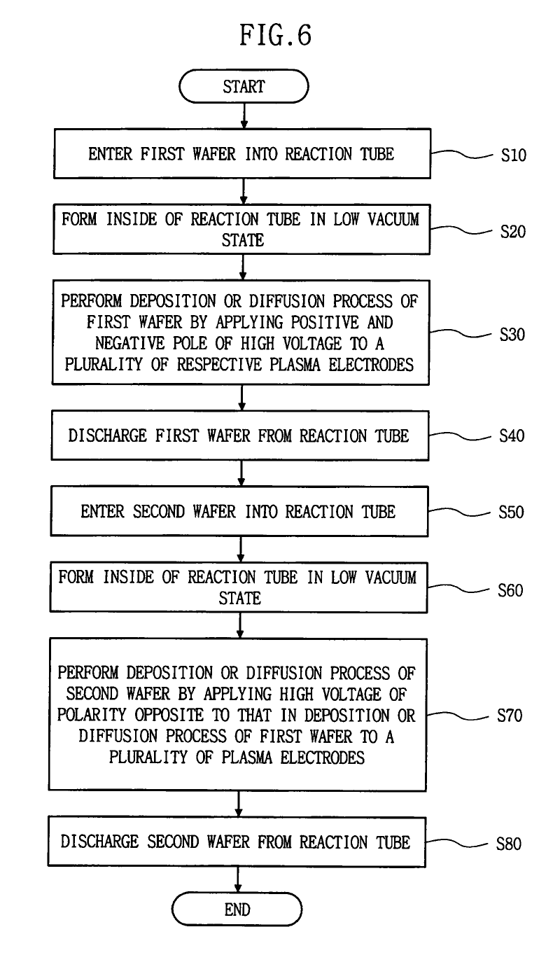

FIG. 6 is a flowchart illustrating a semiconductor manufacturing method according to an embodiment of the invention.

### DETAILED DESCRIPTION

Embodiments of the present invention now will be described more fully hereinafter with reference to the accompanied drawings, in which embodiments of the invention are shown. This invention may, however, be embodied in many different forms and should not be construed as limited to the embodiments set forth herein. Rather these embodiments are provided so that this disclosure will be thorough and complete, and will fully convey the scope of the invention to those skilled in the art.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein. Exemplary embodiments of the present invention are more fully described below with reference to the accompanied drawings. This invention may, however, be embodied in many different forms and should not be construed as being limited to the exemplary embodiments set forth herein; rather, these exemplary embodiments are provided so that this disclosure is thorough and complete, and conveys the concept of the invention to those skilled in the art. For purposes of clarity, a detailed description for well-known functions or configuration has been omitted.

FIG. 1 is a sectional view schematically illustrating a semiconductor manufacturing apparatus according to an embodiment of the invention. FIG. 2 is a plan view of FIG. 1, and FIG. 3 is a perspective view illustrating the reaction tube of FIGS. 1 and 2. FIG. 4 is a plan view illustrating a plasma electrode of FIGS. 1 and 2, and FIG. 5 is a circuit diagram schematically illustrating a switching device.

Referring to FIGS. 1 to 5, and in a semiconductor manufacturing apparatus according to an embodiment of the invention, a plurality of plasma electrodes 60 are mounted outside both sides of a reaction tube 30 adjacent to a spray pipe of reaction gas. The plurality of plasma electrodes 60 have an applied high voltage of DC component for exciting reaction gas sprayed from the reaction tube to a plasma state. The reaction tube 30 is adapted to surround a periphery of boat 20, which is loaded with a multistage plurality of wafers 10.

Further, the semiconductor manufacturing apparatus comprises a high voltage generator 80 for generating high voltage by using a power source supplied from the outside, a switching device 70 for alternately changing a polarity of the high voltage provided from the high voltage generator 80 and applying the voltage to the plurality of plasma electrodes 60, and a controller (not shown) for outputting a control signal to switch the polarity of the high voltage in the switching device 70.

According to an embodiment of the invention, the high voltages applied to the electrodes having mutually different polarities which are alternately applied to the plurality of plasma electrodes 60 to excite a reaction gas to a plasma state. This polarity switching has been found to prevent a build-up of particles on an inner wall of the reaction tube or concentration of ions adjacent the electrodes, thus increasing a production yield by mitigating damage to an inner wall of the reaction tube 30 and reducing the occurrence of particles in the inner wall of the reaction tube.

The reaction tube 30 provides an isolated space in which deposition and diffusion processes are performed by using reaction gas and source gas. For example, the reaction tube 30 is adapted to include an inner tube 34 surrounding a periphery of the plurality of wafers 10 loaded in the boat 20, and an outer tube 32 adapted to seal up a periphery of the inner tube 34 in an outer side of the inner tube 34.

Here the inner tube 34 is provided as a reaction space in which deposition material is deposited on a plurality of wafers 10 while reaction gas and source gas flow. Thus the inner tube 34 is formed with a length corresponding to a stacked height of the plurality of wafers 10 and with an inner diameter larger than a diameter of the plurality of wafers 10. The boat 20 inserted into the inner tube 34 is formed to have a height that is sufficient to load about 70 sheets to about 150 sheets of wafers 10 with a given interval of about 5.5 mm. Further, in an inner wall of the inner tube 34, a second spray pipe 44 for spraying source gas is configured to be arranged in parallel with the long dimension of the boat, that is along a direction in which the plurality of wafers 10 are loaded. The source gas is a silane-group gas of any one of SiH₄, SiH₂Cl₂, Si₂Cl₆ and 3-BIS BTBAS. Though not shown in the drawing, a plurality of multi-holes (not shown) can be formed in the inner tube 34 through which the source gas sprayed from the second spray pipe 44 pass through the plurality of wafers 10 and then flows to the outer tube 32 for evacuation is discussed below.

The outer tube 32 is formed in a bell shape into which the inner tube 34 and the boat 20 are inserted, and is combined with a lower plate 36 of the boat 20 to provide an airtight space. Further, the outer tube is combined with a vacuum pump 39 for pumping air of the interior through an exhaust pipe 38 adapted in a lower part. For example, the vacuum pump 39 is adapted to include a rotary pump or dry pump for pumping air of the outer tube 32 in a low vacuum of about 1×10⁻³ Torr. A heater 50, adapted in an outer circumference face of the outer tube 32, is used to heat the inside of the reaction chamber to a temperature required in the deposition and diffusion processes. The outer and inner tubes 32 and 34 are preferably formed of a transparent quartz material that contains the same or similar silicon to the plurality of wafers 10 so that the plurality of wafers 10 loaded in the inside thereof are shown.

Reaction gas is sprayed from a first spray pipe 42 adapted in parallel with the second spray pipe 44. The first spray pipe 42 is preferably arranged in an inner wall of the outer tube 32 opposite to the exhaust pipe 38 coupled through the outer tube 32,. The reaction gas sprayed from the first spray pipe 42 is excited to a plasma state by an electric field induced in the plurality of plasma electrodes 60, and flows on the plurality of wafers 10. Though not shown in the drawing, the inner tube 34 is provided to pass the reaction gas in a horizontal direction from the first spray pipe 42 mounted in an inner wall of the outer tube 32. A plurality of multi-holes are symmetrically formed in both sides of the inner tube 34 so that the reaction gas sprayed from the first spray pipe 42 flows horizontally and passes on the plurality of wafers 10.

The first spray pipe 42 is formed along the outer tube 32 adjacent to the second spray pipe 44, with the same or similar height as the first spray pipe 42. For example, reaction gas sprayed from the first spray pipe 42 is used containing ammonia (NH₃). Further, the first spray pipe 42 has a configuration like that shown in FIG. 4 so that reaction gas is easy to produce a plasma reaction.

In a preferred embodiment, the outer tube 32 is formed to have a plasma box 40 protruded outside so that the first spray pipe 42 is spaced with a given distance from the inner tube 34 to spray reaction gas. The first spray pipe 42 sprays reaction gas of a given pressure in a center of one side of the plasma box 40 opposed to the inner tube 34 of another side of the plasma box 40. Thus, the plasma box 40 has a space to buffer a spray pressure of reaction gas sprayed from the first spray pipe 42. In addition, a louver 46 is adapted to extend into the interior of the plasma box 40, the louver 46 being adapted to concentrate and direct reaction gas sprayed from the first spray pipe 42 onto the inner tube 34.

For example, when a direction of reaction gas sprayed from the first spray pipe 42 is determined herein to be a first direction, a plurality of plasma electrodes 60 are adapted in an outer wall of both sides of the plasma box 40 in a second direction orthogonal with the first direction. To the plurality of plasma electrodes 60, high voltage is applied that excites the reaction gas sprayed from the first spray pipe 42 to a plasma state. The electric field induced by the high voltage applied to the plurality of plasma electrodes 60 causes the reaction gas to lose negatively charged free electrons. The result is a gas having ions of a plasma state having a positive charge. For example, a distance between the pluralities of plasma electrodes 60 is about 20 mm, and high voltage applied to the plurality of plasma electrodes 60 is a direct current of about 1000V or more.

A drawback to the application of fixedly applied positive and negative poles to the electrodes 60 (thus forming fixed anodes and cathodes) is that ions of a plasma state having a positive charge are attracted to and thus concentrated on the cathode electrode and so the outer tube 32 adjacent to the cathode electrode may be damaged. An important aspect of the invention is that polarity applied to the electrodes 60 are periodically switched to that the anode becomes the cathode and vice versa. Thus the positive pole and the negative pole of high voltage are applied repeatedly and alternately to the plurality of plasma electrodes 60, thereby preventing the outer tube 32 adjacent to any one of the plurality of plasma electrodes 60 from being concentratedly damaged.

The switching device 70 may switch the positive pole and the negative pole of high voltage generated in the high voltage generator 80 and apply the voltage to the plurality of plasma electrodes 60. The switching device 70 may alternately apply the positive pole and the negative pole to the plurality of plasma electrodes 60 according to a repeated number of deposition or diffusion processes performed in the reaction tube 30. For example, when the switching device 70 applies a high voltage of positive and negative polarities to the plurality of respective plasma electrodes 60 in odd-number deposition or diffusion process; in even-number deposition or diffusion process, negative and positive poles of high voltage are applied to the plurality of respective plasma electrodes 60. High voltages of mutually different polarities are applied each time to the plurality of respective plasma electrodes 60, thereby varying the plasma electrodes into the anode electrode and the cathode electrode.

As shown in FIG. 5, the switching device 70 is configured to convert a polarity of high voltage while a switching bar 76 rotates between a power terminal 72 connected to the high voltage generator 80 and an electrode terminal 74 connected with the plurality of plasma electrodes 60. Here the high voltage generator 80 is adapted to generate a high voltage of DC component. Thus a positive pole and a negative pole of high voltage are lockingly applied to a plurality of power terminals 72. For example, the pluralities of power terminals 72 are provided as two.

On the other hand, the plurality of electrode terminals 74 are provided as four, and the electrode terminals 74 coupled with the plurality of plasma electrodes 60 are provided including two positive terminals and two negative terminals. Though not shown in the drawing, the plurality of electrode terminals 74 may be provided as three. Further the switching bars 76 may be provided as two to switch a polarity of high voltage applied to the electrode terminal 74 through the power terminal 72 and thus to bridge between the power terminal 72 and the electrode terminal 74.

The plurality of switching bars 76 rotate in the same direction to switch a polarity of high voltage applied to the plurality of plasma electrodes 60. Thus the switching device 70 rotates the plurality of switching bars 76 in response to a control signal output from a controller and thus can convert a polarity of high voltage applied to the plurality of plasma electrodes 60. It does not matter that the position or the number of the power terminals 72 and the electrode terminals 74 is changed.

In a semiconductor manufacturing apparatus according to an embodiment of the invention, the damage to reaction tube 30 caused by reaction gas ions of a plasma state concentrated on a cathode electrode can be prevented by employing the switching device 70 converting a polarity of high voltage applied to the plurality of plasma electrodes 60, and a pollution of particles generated by a damage of the reaction tube 30 can be prevented, thereby increasing a production yield.

In the configuration described above, a semiconductor manufacturing method using a semiconductor manufacturing apparatus according to an embodiment of the invention is described as follows.

FIG. 6 is a flowchart providing a semiconductor manufacturing method according to an embodiment of the invention.

With reference to FIG. 6, a semiconductor manufacturing method is described as follows.

Pluralities of first wafers are entered into a reaction tube 30 in a step S10. Here the pluralities of first wafers indicate a plurality of wafers 10 undergoing an odd-number deposition or diffusion process within the reaction tube. The plurality of first wafers into the boat and then entered into the reaction tube 30 may be about 70 sheets to about 150 sheets. Further, the boat 20 is adapted to enter the plurality of first wafers into the reaction tube 30 to seal up a lower part of the reaction tube 30 by a plate 36 of a lowermost part.

Then, air from the reaction tube 30 is pumped to produce a low vacuum state in a step S20. At this time the reaction tube 30 is determined as a low vacuum state from a normal pressure by the air pumping of the vacuum pump 39. Thus, inside the reaction tube, an occurrence of pollution material such as particles can be substantially reduced in a subsequent deposition or diffusion process.

And then, a deposition or diffusion process for the plurality of first wafers is performed by applying a high voltage of positive pole and negative pole to the plurality of plasma electrodes 60, in a step S30. Here the plurality of plasma electrodes 60 receive the high voltage and excite the reaction gas into a plasma state, and thus generate a reaction gas ion having a positive charge and a free electron having a negative charge. The reaction gas ion has a very high reaction, thus the deposition or diffusion process can be easily performed. The reaction gas having a positive charge may be concentrated to any one of the plurality of plasma electrodes 60, to which high voltage of a negative pole is applied. Here the plurality of plasma electrodes 60 are positioned outside the reaction tube 30, and the reaction gas flows inside the reaction tube 30. Thus, an inner wall of the reaction tube 30 on which reaction gas ions of the plasma state are concentrated may be easily damaged. Therefore, high voltage with different polarities is applied to the plurality of plasma electrodes 60 in a deposition process or diffusion process of the plurality of first wafers and a plurality of subsequent second wafers, thus the concentrated of reaction gas ions on only one plasma electrode 60 can be prevented.

On the other hand, the deposition or diffusion process may be performed by spraying reaction gas and source gas from the second spray pipe 44 and the first spray pipe 42 adapted inside the reaction tube 30. In one type of deposition process, an atomic layer deposition (ALD) process is included. In the atomic layer deposition technique, reaction precursors formed of source gas and reaction gas are individually separated and flow in a pulse type on the wafer 10. That is, the thin film deposition technique uses a chemical adsorption and desorption through a saturated surface reaction of reaction material on the surface of wafer 10. Thus pluralities of reaction precursors flow with one cycle on the wafer 10, thereby forming a thin film of one layer. Further, reaction materials flowing on the wafer 10 may be three kinds or more. A portion of the reaction materials is used as a necessary component for growing the thin film, and the rest of the material helps a subsequent reaction so as to process a thin film surface by removing one or more ligands etc.

For example, in the atomic layer deposition process using SiH₂Cl₂ or Si₂Cl₆ as source gas and NH₃ as reaction gas, silicon nitride layer may be formed. First, source gas of a given flow amount is supplied through the second spray pipe 44 and flows on the wafer 10 for about 5 seconds to about 20 seconds so that the inside of the reaction tube 30 is filled with the source gas. When a given time lapses, inactive gas or purge gas such as He, Ar, N₂ is supplied into the reaction tube 30 to remove the source gas. Then, reaction gas of a given flow amount through the first spray pipe 42 flows on the wafer 10 for about 3 seconds to about 30 seconds, thus forming an atomic layer thin film such as silicon nitride layer and removing ligand. At this time, the reaction gas is excited into a plasma state by an electric field induced by a high voltage applied to the plurality of plasma electrodes 60. Further, the reaction gas reacts to a precursor of source gas on the surface of the wafer 10, during flowing on the wafer 10, thereby forming a thin film.

Similarly, reaction gas is removed by supplying inactive gas or purge gas into the reaction tube 30. As described above, a thin film such as a silicon nitride layer of a given thickness can be formed by individually supplying source gas and reaction gas through the second and first spray pipes 44 and 42. At this time, after the source gas and the reaction gas are supplied, inactive gas or purge gas is supplied each time into the reaction tube 30. Accordingly, in a semiconductor manufacturing method according to an embodiment of the invention, a deposition process or diffusion process of a plurality of first wafers stacked in a multistage can be performed within the reaction tube 30.

Then, when the deposition or diffusion process for the plurality of first wafers is completed, the boat 20 is discharged from the reaction tube 30 to discharge the plurality of first wafers, in a step S40, and a plurality of second wafers are loaded in boat 20. Here, inactive gas or purge gas is supplied into the reaction tube 30 and the gas is varied to a normal pressure, then the plurality of first wafers may be exposed to the atmosphere. The plurality of first wafers are taken out of the boat 20 by a robot arm, and then are reloaded into a wafer cassette or wafer carrier. And, the plurality of second wafers may be loaded into the boat 20 and then entered into the reaction tube 30 in a step S50. Here, the plurality of second wafers may indicate a plurality of wafers 10 undergoing a deposition or diffusion process of an even-number sequence within the reaction tube 30.

After that, air inside the reaction tube 30 is pumped to produce a low vacuum state in a step S60. As described above, the low vacuum state is provided to substantially reduce an occurrence of pollution material such as particles becoming a factor for defect formation during a deposition or diffusion process for the plurality of second wafers in a subsequent process. In addition, pure reaction gas or source gas is supplied to the reaction tube 30, thereby increasing reproducibility of the deposition or diffusion process.

Then, high voltage having a polarity opposite to that in the deposition or diffusion process for the plurality of first wafers is applied to the plurality of plasma electrodes 60. Thereafter, the deposition or diffusion process for the plurality of second wafers is performed in a scheme similar to the deposition or diffusion process for the plurality of first wafers. But, the switching device 70 switches a polarity of high voltage applied to the plurality of plasma electrodes 60, opposite to that in the deposition or diffusion process for the plurality of first wafers. For example, when a positive pole (first electrode) and a negative pole (second electrode) of high voltage are applied to the plurality of respective plasma electrodes 60 in the deposition or diffusion process for the plurality of first wafers, a negative pole (first electrode) and a positive pole (second electrode) are applied to the plurality of respective plasma electrodes 60 in the deposition or diffusion process for the plurality of second wafers.

The plurality of plasma electrodes each become an anode electrode and a cathode electrode in a deposition or diffusion process for a plurality of first wafers, and switch to becoming a cathode electrode and an anode electrode in a deposition process or diffusion process for a plurality of second wafers. In the plurality of plasma electrodes 60, an anode electrode and a cathode electrode are switched each time according to a sequence the deposition or diffusion process is performed.

Accordingly, in a semiconductor manufacturing method according to an embodiment of the invention, high voltages of mutually different polarities are applied each time to the plurality of plasma electrodes 60 according to a sequence the deposition or diffusion process is performed for a plurality of wafers 10. This action has been found to thereby prevent an inner wall of reaction tube 30 from having concentrations of the plasma reaction gas, thereby damaging it, with the result that production yield is increased. As the deposition or diffusion process for the first group of wafers has already been described, further description of the source gas and reaction gas used in a deposition or diffusion process for a plurality of second wafers is omitted herein.

Then, when the deposition or diffusion process for the plurality of second wafers is completed, the plurality of second wafers are discharged from the reaction tube 30 in a step S80, and a new set of wafers is loaded into the reaction tube 30.

Though not shown in the drawing, a polarity of high voltage applied to a plurality of plasma electrodes 60 is alternately switched in repeatedly performing a deposition or diffusion process for a plurality of first and second wafers.

Consequently, in a semiconductor manufacturing method according to an embodiment of the invention, a polarity of high voltage is applied to a plurality of respective plasma electrodes 60 as a deposition or diffusion process for a plurality of wafers 10 is performed in an odd-number sequence or even-number sequence within the reaction tube 30.

According to some embodiments of the invention, the damage to the reaction tube causable by reaction gas ions in a plasma state being concentrated on a cathode electrode can be prevented by using a switching device converting a polarity of high voltage applied to a plurality of plasma electrodes. The potential pollution of particles generated by a damage of the reaction tube can be prevented, thereby increasing a production yield.

It will be apparent to those skilled in the art that modifications and variations can be made in the present invention without deviating from the spirit or scope of the invention. Thus, it is intended that the present invention cover any such modifications and variations of this invention provided they come within the scope of the appended claims and their equivalents. Accordingly, these and other changes and modifications are seen to be within the true spirit and scope of the invention as defined by the appended claims.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor manufacturing apparatus comprising:
a boat for storing a plurality of wafers;
a reaction tube surrounding a periphery of the boat;
a first spray pipe arranged outside an inner wall of the reaction tube for spraying reaction gas to the plurality of wafers stored in the boat; and
a plurality of plasma electrodes positioned on either side of the first spray pipe and configured to create a plasma state in the reaction gas exiting the first spray pipe by applying in a first process a first high voltage polarity of DC (Direct Current) to at least a first of the plasma electrodes and a second high voltage polarity of DC to at least a second of the plasma electrodes, arranged on an opposite side of the first spray pipe to the first, and in a second process applying to the electrodes a polarity inverted from that applied in the first process.

2. The apparatus of claim 1, further comprising:
a high voltage generator for generating the high voltage by using a power source supplied from the outside;
a switching device for switching the polarity of the high voltage generated in the high voltage generator and applying the voltage to the plurality of plasma electrodes; and
a controller for outputting a control signal to switch the polarity of the high voltage.

3. The apparatus of claim 2, wherein the first and second processes each are a deposition or diffusion process and are performed within the reaction tube, wherein the switching device is configured to switch the polarity of the high voltage applied to the plurality of plasma electrodes after the deposition or diffusion is performed.

4. The apparatus of claim 2, wherein the switching device comprises:
a plurality of power terminals coupled to the high voltage generator;
a plurality of electrode terminals coupled with the plurality of plasma electrodes; and
a plurality of switching bars bridging and switched between the plurality of electrode terminals and the plurality of power terminals.

5. The apparatus of claim 4, wherein the plurality of power terminals are two, the plurality of electrode terminals are between three and four, and the plurality of switching bars are two.

6. The apparatus of claim 5, wherein the plurality of switching bars rotate in the same direction.

7. The apparatus of claim 1, wherein the reaction tube comprises an inner tube surrounding a periphery of the plurality of wafers loaded in the boat, and an outer tube adapted to seal up a periphery of the inner tube in an outer side of the inner tube.

8. The apparatus of claim 7, wherein the outer tube and the inner tube are formed of transparent quartz material.

9. The apparatus of claim 8, wherein an inner wall of the outer tube is provided with the first spray pipe for spraying reaction gas into the inner tube from the outside thereof.

10. The apparatus of claim 9, further including a plasma box protruding from the outer tube and enclosing the first spray pipe.

11. The apparatus of claim 10, wherein the outer tube comprises a louver extending into the interior of the plasma box, the louver being configured to direct the reaction gas sprayed from the first spray pipe into the inner tube.

12. The apparatus of claim 10, wherein the plurality of plasma electrodes are arranged on both sides of an outer wall of the plasma box with respect to the first spray pipe.

13. The apparatus of claim 8, further including a second spray pipe positioned in an inner wall of the inner tube and arranged in parallel to the first spray pipe, said second spray pipe being configure to spray a source gas at a side face of the plurality of wafers loaded into the boat.

14. A semiconductor manufacturing method, comprising:
entering a plurality of first wafers loaded in a boat into a reaction tube;
applying a high voltage direct current (DC) of a first polarity arrangement to a plurality of plasma electrodes during a supply of reaction gas into the reaction tube to thus excite the reaction gas to a plasma state;
performing a deposition or diffusion process forming a thin film of a given thickness on the plurality of first wafers by supplying source gas in the plasma state into the reaction tube;
discharging the plurality of first wafers from the reaction tube, and entering a plurality of second wafers into the reaction tube; and
applying a DC high voltage to the plurality of plasma electrodes of a second polarity arrangement, opposite to the first polarity arrangement, while reaction gas is supplied into the reaction tube, and exciting the reaction gas to a plasma state, and then performing a deposition or diffusion process to form a thin film on the plurality of second wafers by supplying the source gas into the reaction tube.

15. The method of claim 14, wherein the source gas comprises SiH₂Cl₂ or Si₂Cl₆, and the reaction gas comprises ammonia.

16. The method of claim 14, wherein the deposition or diffusion process for the plurality of first wafers and the plurality of second wafers comprises:
individually alternately spraying the reaction gas and the source gas into the reaction tube; and
spraying an inactive gas or purge gas before and after the reaction gas and the source gas are individually sprayed.

17. A semiconductor manufacturing apparatus comprising:
a reaction tube configured to hold one or more wafers;
a spray pipe coupled to the reaction tube for spraying reaction gas into the reaction tube;
a cathode and an anode plasma electrode arranged for exciting reaction gas exiting the spray pipe to a plasma state prior to entry into the reaction tube; and
a switching device coupled to both the cathode and anode plasma electrode and configured to switch a polarity of a high voltage applied to each of the cathode and anode.

18. The semiconductor manufacturing apparatus of claim 17, wherein the switching device includes a plurality of power terminals coupled to the high voltage generator and a plurality of switching bars bridging and switched between the cathode and anode electrodes and the plurality of power terminals.

19. The semiconductor manufacturing apparatus of claim 18, wherein the plurality of switching bars rotate in the same direction.

20. The semiconductor manufacturing apparatus of claim 17, wherein the reaction tube includes an outer tube and an inner tube sealed within the outer tube, the apparatus further including:
a second spray pipe adjacent the inner tube for spraying a source gas into the reaction tube, said second spray pipe arranged in parallel with said first spray pipe;
a plasma box protruding from an outer wall of the outer pipe and including the first spray pipe and cathode and anode plasma electrode; and
a louver configured to guide the reaction gas from the first spray pipe into the inner tube.
